(19) United States
(12) Patent Application Publication
(10) Pub. No.: US 2008/0011451 A1
(43) Pub. Date: Jan. 17, 2008

(54) HEAT SINK FOR ELECTRONIC DEVICE

(75) Inventors: Ning-Yu Wang, Shenzhen (CN); Zhi-Jiang Yao, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,210

(22) Filed: Jul. 13, 2006

(51) Int. Cl. H05K 7/20

(52) U.S. Cl. 165/80.3; 361/704; 257/720

(57) ABSTRACT

A heat sink includes a dissipating heat element and a thermal conducting element securely mounted on the dissipating heat element. The dissipating heat element has a base and a plurality of fins extending from the base. The base defines a cavity therein. The thermal conducting element has an inserting portion inserting in the cavity of the dissipating heat element, and a contacting portion for being in contact with an electronic device to thereby conduct heat generated by the electronic device to the dissipating heat element. A cross-sectional area of the contacting portion of the thermal conducting element is larger than that of the inserting portion of the thermal conducting element.

### 1. FIELD OF THE INVENTION

The present invention relates to heat sinks, and more particularly to a heat sink for cooling electronic devices.

### 2. DESCRIPTION OF RELATED ART

With the rapid development of computer technology, a new electronic device such as a central processing unit (CPU) can perform more and more functions. The central processing unit (CPU) is the core administrator of electrical signals in most contemporary personal computers. During operation of the CPU, large amounts of heat are generated. Such heat must be quickly removed from the CPU, to prevent the CPU from becoming unstable or being damaged. Typically, a heat sink together with a fan is attached to an outer surface of the CPU to facilitate removal of heat therefrom.

A conventional heat sink includes a base and a plurality of fins extending up from the base. A bottom portion of the base is secured in contact with an electronic device such as a central processing unit (CPU), to conduct heat from the device to the fins. Such heat generated by the device is then dissipated via the fins. The base and the fins are often integrally made of aluminum or aluminum alloy. Aluminum and aluminum alloy have relatively low coefficients of heat conduction. Thus, the heat generated by the device is not effectively transferred to the base and fins.

A typical heat sink is shown in FIG. 5. The heat sink 10 includes a base 12 made of aluminum or aluminum alloy, and a plurality of fins 14 extending up from the base 12. A bottom surface of the base 12 defines a recess 16 therein. An electronic device (not shown), which generates heat during operation, is received in the recess 16 of the base 12. The device is contacted with at least one sidewall and a bottom wall of the recess 16 for increasing contact area. Thus, more heat is transferred to the base 12. However, increasing contact area does not improve heat dissipation substantially. Therefore, an improved heat sink is strongly desired.

What is needed, therefore, is to provide a heat sink, that has two different materials for improving heat conductivity.

### SUMMARY OF THE INVENTION

In one aspect, a heat sink includes a dissipating heat element and a thermal conducting element securely mounted on the dissipating heat element. The dissipating heat element has a base and a plurality of fins extending from the base. The base defines a cavity therein. The thermal conducting element has an inserting portion for inserting in the cavity of the dissipating heat element, and a contacting portion for being in contact with an electronic device to thereby conduct heat generated by the electronic device to the dissipating heat element. A cross-sectional area of the contacting portion of the thermal conducting element is larger than that of the inserting portion of the thermal conducting element.

In another aspect, a heat sink for dissipating heat from an electronic device includes a dissipating heat element including a base and a plurality of fins extending from the base, and a thermal conducting element sandwiched between the dissipating heat element and the electronic device. The base defines a cavity therein. The thermal conducting element has an inserting portion inserting into the cavity of the base, and a contacting portion located outside the cavity for contacting with the electronic device to thereby conduct heat generated by the electronic device to the dissipating heat element.

In still another aspect, a heat sink includes a base having a first side and an opposite second side, a plurality of first fins extending from the second side, and a thermal conducting element. A cavity is defined in the first side of the base, and the base has a post extending into the cavity. The thermal conducting element is engagingly received in the cavity, and the thermal conducting element has a receiving space engagingly receiving the post. The thermal conducting element is made of a material with a greater heat conductive coefficient than that of the base. The thermal conducting element is configured for thermally contacting a heat source and conducting the heat from the heat source to the base.

Other advantages and novel features will be drawn from the following detailed description of preferred embodiment with the attached drawings, in which:

### BRIEF DESCRIPTION OF THE DRAWINGS

FIG. 1 is an exploded, isometric view of a heat sink in accordance with a first embodiment of the present invention including a dissipating heat element, and a thermal conducting element fixed to the dissipating heat element;

FIG. 2 is a cross-sectional view of the heat sink of FIG. 1, with the thermal conducting element fixed to the dissipating heat element;

FIG. 3 is an exploded, isometric view of a heat sink in accordance with a second embodiment of the present invention including a dissipating heat element, and a thermal conducting element fixed to the dissipating heat element;

FIG. 4 a cross-sectional view of the heat sink of FIG. 3, with the thermal conducting element fixed to the dissipating heat element; and

FIG. 5 is an isometric view of a conventional heat sink.

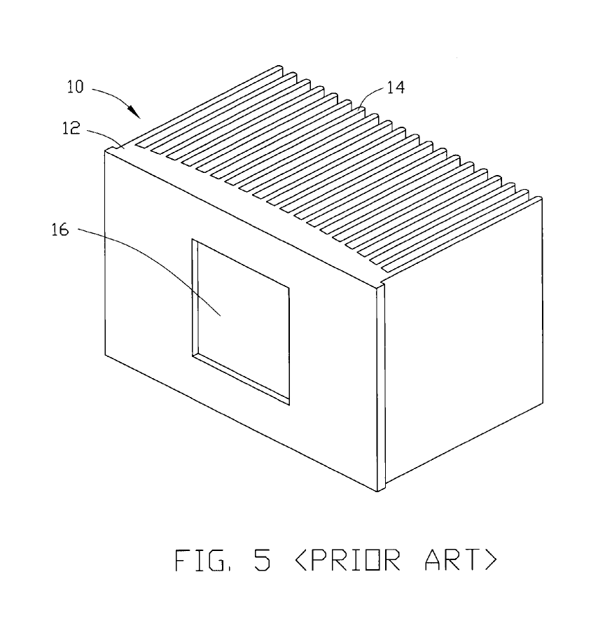

### DETAILED DESCRIPTION OF THE INVENTION

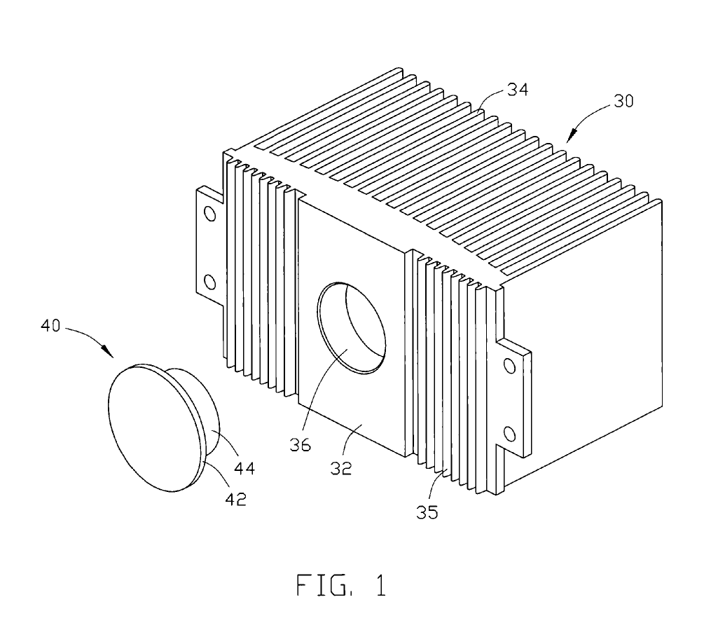

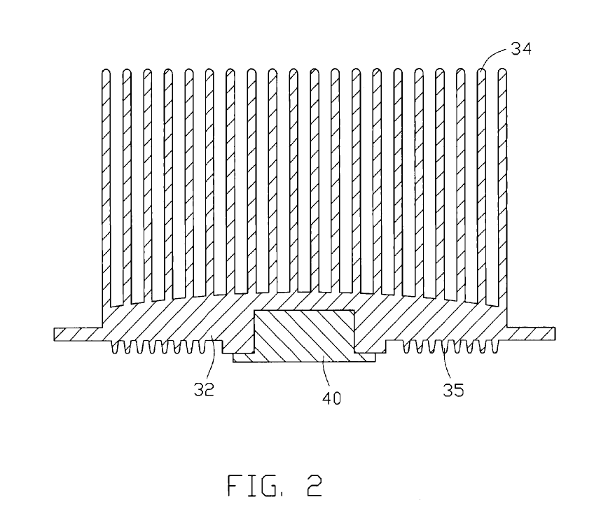

Referring to FIGS. 1 and 2, a heat sink in accordance with a first embodiment of the present invention includes a dissipating heat element 30, and a thermal conducting element 40 mounted on the dissipating heat element 30. Typically, the thermal conducting element 40 is often made of a first material such as copper or copper alloy, and the dissipating heat element 30 is usually made of a second material such as aluminum or aluminum alloy since the coefficient of heat conduction of copper (359 w/cm. k) is much higher than that of aluminum (207 w/cm. k).

The dissipating heat element 30 includes a base 32, and a plurality of spaced first fins and second fins 34, 35 extending out from two opposite sides of the base 32 respectively. A central portion of a bottom surface of the base 32 defines a circular cavity 36 therein. A fan (not shown) may be mounted on top ends or side ends of the first fins 34 for generating airflow across the dissipating heat element 30.

The thermal conducting element 40 includes a disk-shaped contacting portion 42, and a columniform inserting portion 44 extending up from the contacting portion 42. A height of the inserting portion 44 is equal to a depth of the cavity 36 of the dissipating heat element 30, and a diameter of a cross section of the inserting portion 44 is slightly larger than a diameter of a cross section of the cavity 36 of the dissipating heat element 30. The contacting portion 42 is secured in contact with an electronic device such as a central processing unit (CPU), to conduct heat from the electronic device to the dissipating heat element 30. The cross-sectional area of the contacting portion 42 is larger than that of the inserting portion 44.

In assembly, the inserting portion 44 of the thermal conducting element 40 is received by the cavity 36 of the dissipating heat element 30 resulting in tight contact between an exterior surface of the inserting portion 44 and an internal surface of the cavity 36. Simultaneously, a top surface of the contacting portion 42 tightly contacts with the bottom surface of the base 32 of the dissipating heat element 30. Accordingly, the heat generated by the electronic device is substantially conducted to the dissipating heat element 30. Alternatively, a cross section of the contacting portion 42 and the inserting portion 44 may be in a shape of polygon such as a quadrilateral, a pentagon, or a hexagon.

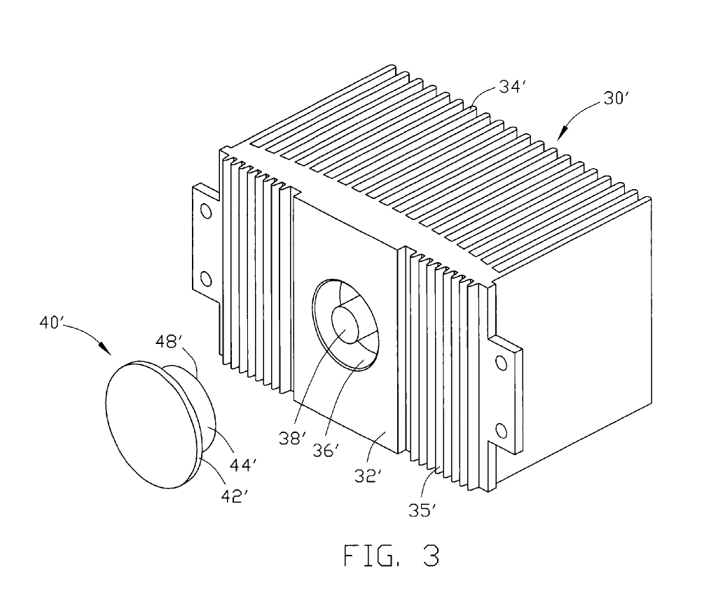

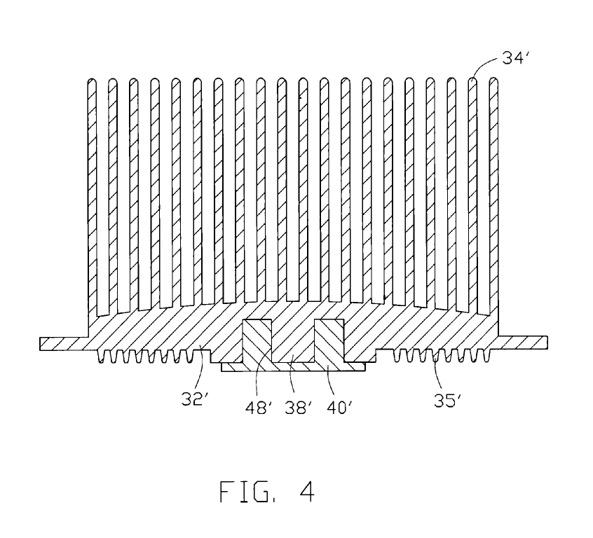

Referring to FIGS. 3 and 4, a heat sink in accordance with a second embodiment of the present invention includes a dissipating heat element 30′, and a thermal conducting element 40′ mounted on the dissipating heat element 30′.

The dissipating heat element 30′ is similar to the dissipating heat element 30 of the first preferred embodiment, except that the dissipating heat element 30′ has a circular post 38′ extending out from a middle portion of a cavity 36′ of the dissipating heat element 30′. As such, the thermal conducting element 40′ is similar to the thermal conducting element 40 of the first preferred embodiment, except that the inserting portion 44′ of the thermal conducting element 40′ defines a circular receiving space 48′ at a central portion thereof, corresponding to the circular post 38′ of the dissipating heat element 30′. A height of the circular post 38′ of the dissipating heat element 30′ is equal to a depth of the receiving space 48′ of the thermal conducting element 40′. A diameter of a cross section of the post 38′ of the dissipating heat element 30′ is slightly larger than a diameter of a cross section of the receiving space 48′ of the thermal conducting element 40′.

In assembly, the inserting portion 44′ of the thermal conducting element 40′ is pressed into the cavity 36′ of the dissipating heat element 30′. Simultaneously, the circular post 38′ inserts into the receiving space 48′ of the thermal conducting element 40′. An exterior surface of the inserting portion 44′ is thus in tight contact with an internal surface of the cavity 36′ of the dissipating heat element 30′. Similarly, an exterior surface of the post 38′ of the dissipating heat element 30′ is in tight contact with an internal surface of the receiving space 48′ of the thermal conducting element 40′. Furthermore, a top surface of the contacting portion 42′ is in tight contact with the bottom surface of the base 32′ of the dissipating heat element 30′. Accordingly, the heat generated by the electronic device is substantially conducted to the dissipating heat element 30′. Alternatively, cross sections of the contacting portion 42′, the inserting portion 44′, and the post 38′ may have a polygon shape such as a quadrilateral, a pentagon or a hexagon.

While the present invention has been illustrated by the description of preferred embodiments thereof, and while the preferred embodiments have been described in considerable detail, it is not intended to restrict or in any way limit the scope of the appended claims to such details. Additional advantages and modifications within the spirit and scope of the present invention will readily appear to those skilled in the art. Therefore, the present invention is not limited to the specific details and illustrative examples shown and described.

What is claimed is:

1. A heat sink comprising:
a dissipating heat element comprising a base and a plurality of fins extending from the base, the base defining a cavity therein; and
a thermal conducting element securely mounted on the dissipating heat element, the thermal conducting element having an inserting portion inserting into the cavity of the dissipating heat element, and a contacting portion for being in contact with an electronic device to thereby conduct heat generated by the electronic device to the dissipating heat element;
wherein a cross-sectional area of the contacting portion of the thermal conducting element is larger than that of the inserting portion of the thermal conducting element.

2. The heat sink as described in claim 1, wherein the thermal conducting element is made of a first material and the dissipating heat element is made of a second material, and the coefficient of heat conduction of the first material is larger than that of the second material.

3. The heat sink as described in claim 2, wherein the first material is copper or copper alloy, and the second material is aluminum or aluminum alloy.

4. The heat sink as described in claim 1, wherein a height of the inserting portion of the thermal conducting element is equal to a depth of the cavity of the dissipating heat element.

5. The heat sink as described in claim 1, wherein a diameter of a cross section of the inserting portion is slightly larger than a diameter of a cross section of the cavity of the dissipating heat element before insertion of the inserting portion into the cavity.

6. The heat sink as described in claim 1, wherein a cross section of the inserting portion of the thermal conducting element is a polygon.

7. The heat sink as described in claim 1, wherein the inserting portion of the thermal conducting element defines a receiving space therein, and a post extends out from the cavity of the dissipating heat element for inserting in the receiving space.

8. The heat sink as described in claim 7, wherein a height of the post of the dissipating heat element is equal to a depth of the receiving space of the thermal conducting element.

9. The heat sink as described in claim 7, wherein a diameter of a cross section of the post of the dissipating heat element is slightly larger than a diameter of a cross section of the receiving space of the thermal conducting element before insertion of the post into the receiving space.

10. The heat sink as described in claim 7, wherein a cross section of the post of the dissipating heat element is a polygon.

11. A heat sink for dissipating heat from an electronic device comprising:
a dissipating heat element comprising a base and a plurality of fins extending from the base, the base defining a cavity therein; and
a thermal conducting element sandwiched between the dissipating heat element and the electronic device, the thermal conducting element having an inserting portion inserting into the cavity of the dissipating heat element, and a contacting portion located outside the cavity for contacting with the electronic device to thereby conduct heat generated by the electronic device to the dissipating heat element.

12. The heat sink as described in claim 11, wherein the thermal conducting element is made of a first material and the dissipating heat element is made of a second material, and the coefficient of heat conduction of the first material is larger than that of the second material.

13. The heat sink as described in claim 12, wherein the first material is copper or copper alloy, and the second material is aluminum or aluminum alloy.

14. The heat sink as described in claim 11, wherein a cross-sectional area of the contacting portion of the thermal conducting element is larger than that of the inserting portion of the thermal conducting element.

15. The heat sink as described in claim 11, wherein a diameter of a cross section of the inserting portion is slightly larger than a diameter of a cross section of the cavity of the dissipating heat element before insertion of the inserting portion into the cavity.

16. The heat sink as described in claim 11, wherein the inserting portion of the thermal conducting element defines a receiving space therein, and a post extends out from the cavity of the dissipating heat element for inserting in the receiving space.

17. The heat sink as described in claim 16, wherein a height of the post of the dissipating heat element is equal to a depth of the receiving space of the thermal conducting element.

18. The heat sink as described in claim 16, wherein a diameter of a cross section of the post of the dissipating heat element is slightly larger than a diameter of a cross section of the receiving space of the thermal conducting element before insertion of the post into the receiving space.

19. A heat sink comprising:
a base having a first side and an opposite second side, a cavity being defined in the first side, the base including a post extending into the cavity;
a plurality of first fins extending from the second side; and
a thermal conducting element engagingly received in the cavity, the thermal conducting element having a receiving space engagingly receiving the post, the thermal conducting element being made of a material with a greater heat conductive coefficient than that of the base, the thermal conducting element being configured for thermally contacting a heat source and conducting the heat from the heat source to the base.

20. The heat sink of claim 19 further including a plurality of second fins extending from the first side of the base.
